(19) United States
(12) Patent Application Publication
(10) Pub. No.: US 2005/0170589 A1
(43) Pub. Date: Aug. 4, 2005

(54) Method for forming mask ROM

(76) Inventors: Chien-Hsing Lee, Jhubei City (TW); Chin-Hsi Lin, Hsinchu (TW); Jhyy-Cheng Liou, Jhubei City (TW)

Correspondence Address: J C PATENTS, INC., 4 VENTURE, SUITE 250, IRVINE, CA, 92618, US

(21) Appl. No.: 10/886,784

(22) Filed: Jul. 7, 2004

Related U.S. Application Data
(60) Provisional application No. 60/541,843, filed on Feb. 3, 2004.

(51) Int. Cl. H01L 21/8236; H01L 21/336

(52) U.S. Cl. 438/278

(57) ABSTRACT

The present invention relates to a fabrication method for a mask read only memory structure. By forming double spacers, the code implantation can be performed in a self-aligned way into the channel regions of predetermined memory cells. By avoiding erroneous implantation to the non-channel regions and thus the laterally diffusion of the un-wanted impurities to the channel regions of non-coded memory cells, the threshold voltage of the non-coded memory cells can be unaffected and the error rate of reading can be greatly reduced.

### CROSS-REFERENCE TO RELATED APPLICATION

This application claims the priority benefits of U.S. provisional application titled “Self Align ROM Code implantation of NAND ROM” filed on Feb. 3, 2004, Ser. No. 60/541,843. All disclosure of this application is incorporated herein by reference.

### BACKGROUND OF THE INVENTION

1. Field of Invention

The present invention relates to a mask read only memory. More particularly, the present invention relates to a method for forming a mask read only memory with self-aligned code implantation.

2. Description of Related Art

Generally, the mask read only memory (ROM) can be divided as NOR type mask ROM and NAND type mask ROM. Although the NOR type mask ROM usually affords larger cell currents, the fabrication processes are more complicated. On the other hand, the NAND type Mask ROM can provide dense cell sizes and employ fabrication processes compatible with the standard Logic processes.

In general, for the conventional mask ROM, each memory cell can be programmed to store only one bit data (i.e. either “0” or “1”) at one time. For the NAND type mask ROM cell programming, the stored logic data is either “0” or “1” depending on whether the ions are implanted into the channel regions or not. Such implantation process, implanting ions or dopants into the specific channel regions beneath the word lines, is so called code implantation process.

The NAND type ROM memory consists of series MOS transistors, including depletion mode MOS transistors and enhancement mode MOS transistors. Providing the intrinsic MOS transistor is the enhancement mode NMOS transistor and the threshold voltage is positive, the ROM code implantation implants impurities into the channel region of the depletion mode NMOS transistor and changes its threshold voltage to be negative.

However, the threshold voltage of non-coded memory cells may be disturbed to result in errors in memory reading, due to misalignment of code implantation photomask. In the occurrence of misalignment, the code impurities are mistakenly implanted into the regions outside the channel regions and the impurities will laterally diffuse to adjacent non-coded memory cells. Therefore, the threshold voltage of non-coded memory cells will be altered and the non-coded memory cells become semi-coded or coded, which may cause errors in reading memory data.

### SUMMARY OF THE INVENTION

Accordingly, in order to reduce the errors rates caused by misalignment, a method for forming a mask ROM with self-aligned ROM code implant is provided.

The present invention provides a method of fabricating a mask ROM structure by forming double spacers for aiding self-aligned ROM code implantation, which is compatible with the conventional mask ROM fabrication process. By forming the double spacers covering the underlying substrate, the code implantation can be performed in a self-aligned way into the channel regions of predetermined memory cells. Because erroneous implantation to the non-channel regions and the subsequently laterally diffusion of the un-wanted impurities to the channel regions of non-coded memory cells are avoided, the threshold voltage of the non-coded memory cells can be unaffected and the error rate of reading can be greatly reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic view showing the threshold voltage distribution of the ROM memory cell according to the first scenario.

FIG. 1B is a schematic view showing the threshold voltage distribution of the ROM memory cell according to the second scenario.

FIG. 1C is a schematic view showing the impurity concentration distribution of the ROM memory cell according to the first scenario.

FIG. 1D is a schematic view showing the impurity concentration distribution of the ROM memory cell according to the second scenario.

FIGS. 2A-2I are schematic cross-sectional views of process steps for forming a mask ROM memory cell according to the first preferred embodiment of the present invention.

FIGS. 3-8 are schematic cross-sectional views of process steps for forming a mask ROM memory cell according to the second preferred embodiment of the present invention.

FIGS. 9-11 are schematic cross-sectional views of process steps for forming a mask ROM memory cell according to the third preferred embodiment of the present invention.

### DESCRIPTION OF THE PREFERRED EMBODIMENTS

The method for forming a mask ROM structure provided by this invention comprises performing the ROM code implant process in a self-aligned way.

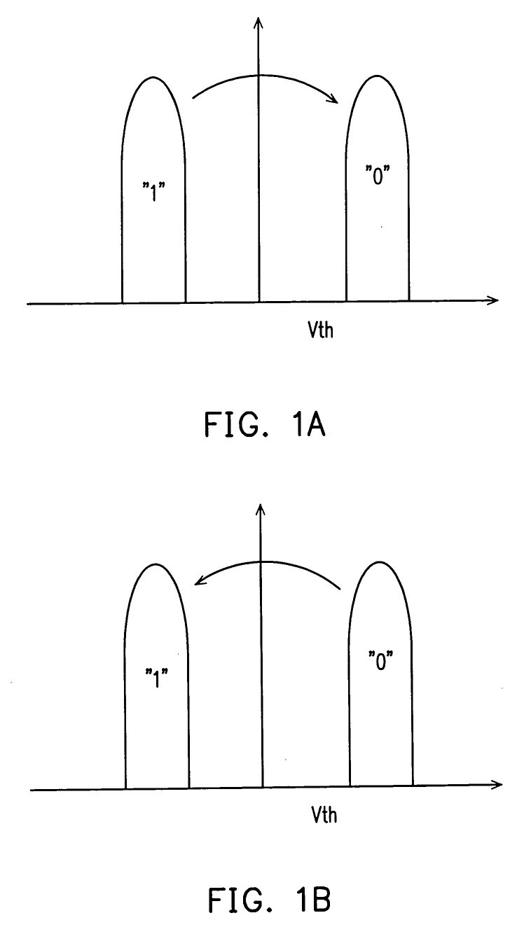

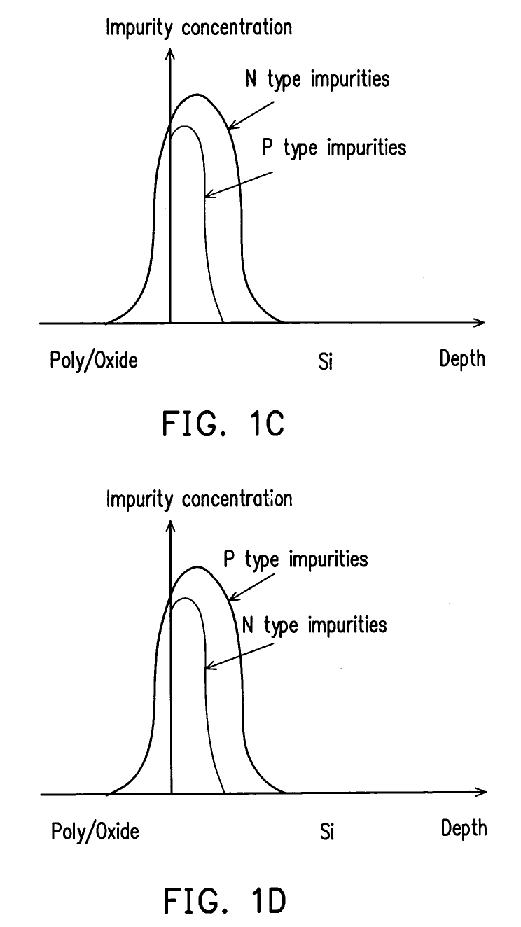

Moreover, according to the method of this invention, the ROM code implantation can be implanted into channel regions of either depletion mode transistors or enhancement mode transistors. According to the first scenario, as the intrinsic MOS transistor is the depletion mode NMOS transistor and the threshold voltage is negative, the ROM code implantation implants impurities into the channel region of the enhancement mode NMOS transistor and changes its threshold voltage to be positive, as shown in FIG. 1A. According to the second scenario, if the intrinsic MOS transistor is the enhancement mode NMOS transistor and the threshold voltage is positive, the ROM code implantation implants impurities into the channel region of the depletion mode NMOS transistor and changes its threshold voltage to be negative, as shown in FIG. 1B. The impurity concentration distributions of the ROM memory cell regarding to the above first and second scenarios of the ROM code implantation are shown respectively in FIGS. 1C and 1D.

In the present invention, the method for forming the mask ROM preferably is applied for NAND type mask ROM.

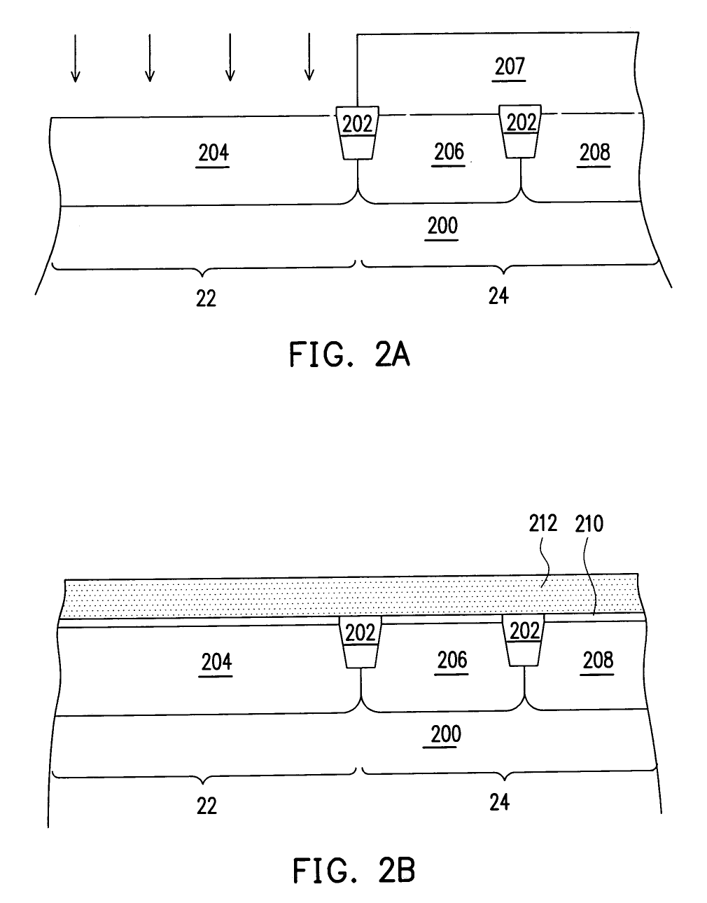

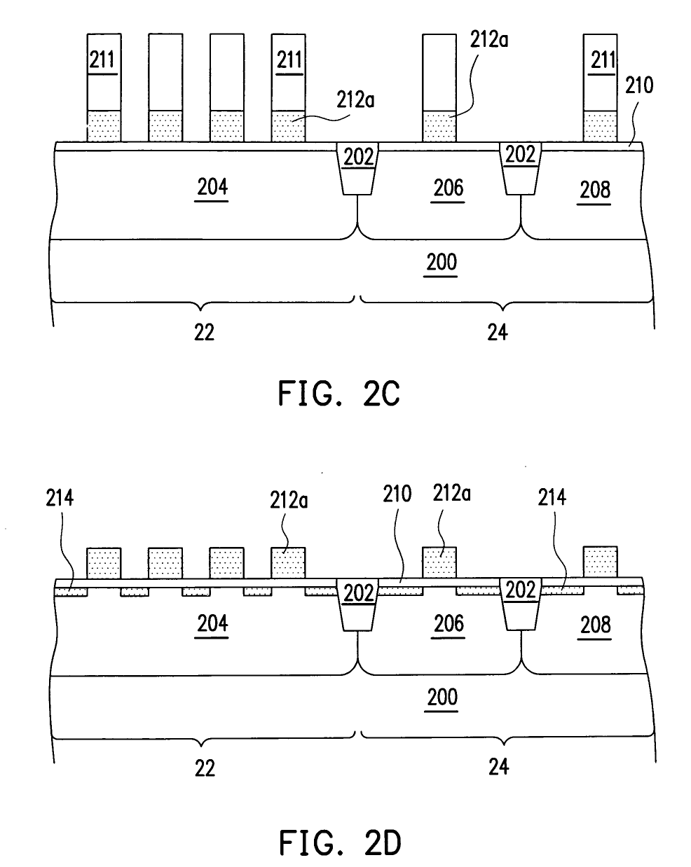

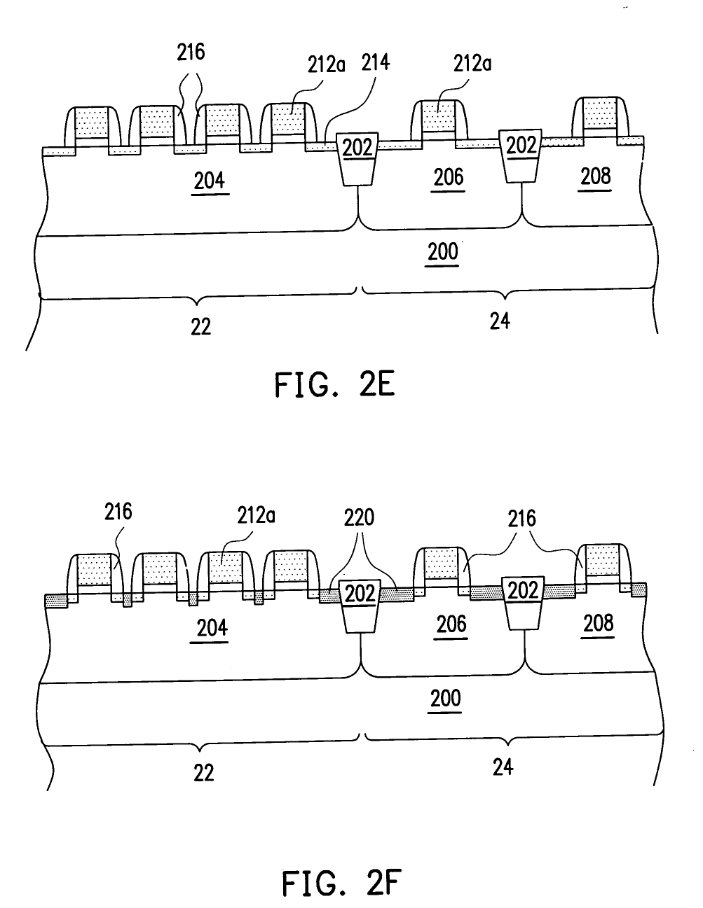

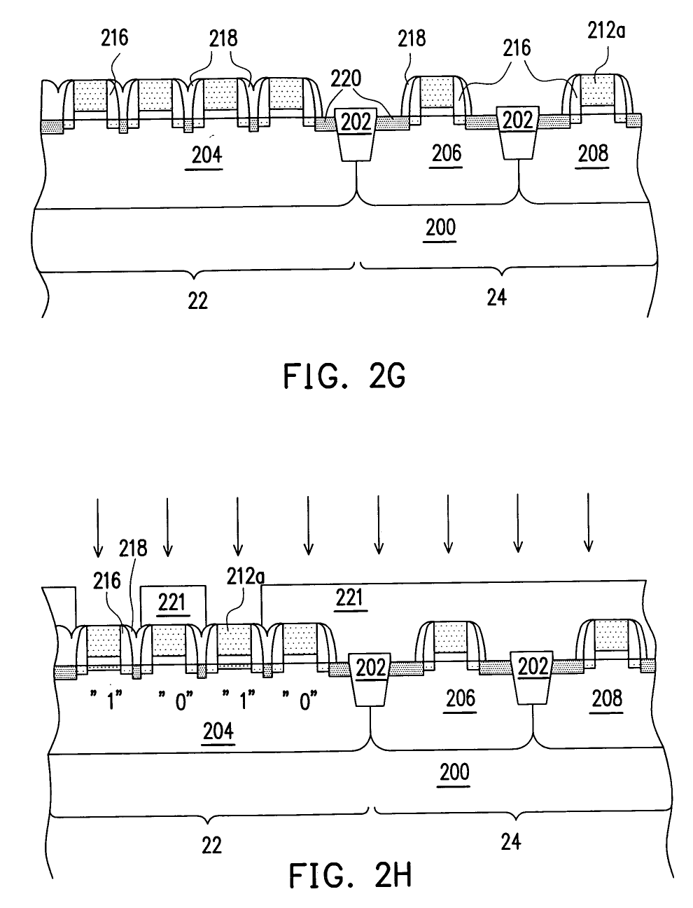

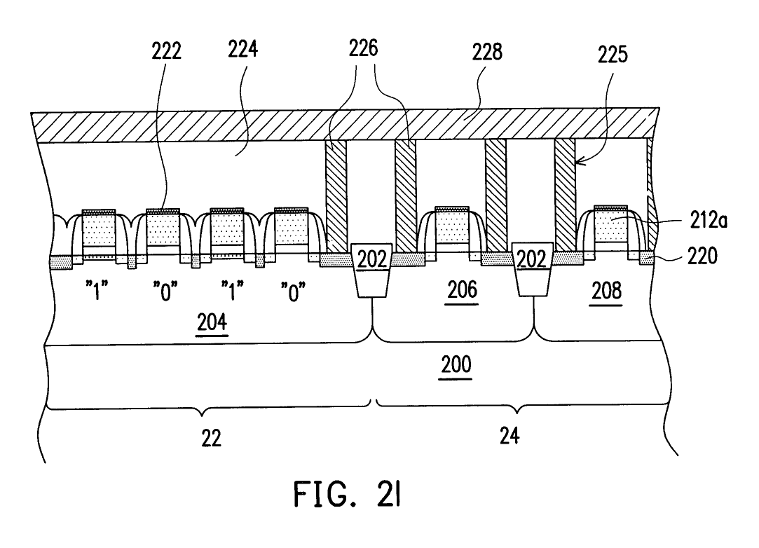

FIGS. 2A-2I are schematic cross-sectional views of process steps for forming the mask ROM memory cell according to the first preferred embodiment of the present invention.

In FIG. 2A, a substrate 200 having a plurality of isolation structures 202 is provided. The substrate 200 can be P-type substrate, and the isolation structure can be a shallow trench isolation (STI) structure, for example. The substrate 200 includes at least a memory region 22 and a periphery region 24. After well implantation and thermal treatment under 950-1100° C., a plurality of N-type wells (N-wells) and a plurality of P-type wells (P-wells) are formed in the substrate 200. The memory region 22 includes at least a P-type well 204, while the periphery region 24 includes at least a N-type well 206 and a P-type well 208. Then, after applying the first patterned photoresist layer 207 as a mask, P-type impurities are implanted (cell Vt implantation) to adjust the memory cell threshold voltage (Vt) in the memory region, so that the memory cell subsequently becomes the enhancement mode NMOS transistor. In addition, P-type impurities can be implanted through the isolation structures as “channel stopper” to improve cell field isolation. Afterwards, the first patterned photoresist layer 207 is removed.

Referring to FIG. 2B, a gate oxide layer 210 and a gate conductive layer 212 are sequentially formed on the substrate 200. The gate conductive layer is, for example an undoped polysilicon layer having a thickness of about 2000-4000 Angstroms. If the gate conductive layer is an undoped polysilicon layer, N-type impurities are implanted into the undoped gate conductive layer above the P-wells, and P-type impurities are then implanted into the undoped gate conductive layer above the N-wells, by using different patterned photoresist masks. Alternatively, the gate conductive layer 212 can be a doped polysilicon layer formed by in-situ doping, for example.

In FIG. 2C, after applying the second patterned photoresist layer 211 as a mask, the gate conductive layer 212 is patterned by, for example, performing dry etching. The patterned gate conductive layer 212a acts as word line(s) of the NAND type ROM cell.

Referring to FIG. 2D, using the patterned gate conductive layer 212a as a mask, LDD implantation is performed to form LDD regions 214 in the substrate 200 along both sides of the patterned gate conductive layer 212a. For example, N-type LDD impurities are implanted into the P-wells using the N-doped gate conductive layer as masks and with the N-well covered, and P-type LDD impurities are later implanted into the N-well using the P-doped gate conductive layer as mask and with the P-wells covered.

Afterwards, spacers 216 are formed on the sidewalls of the patterned gate conductive layer 212a. For example, the spacers 216 can be formed by first blanketly forming a silicon oxide layer or a silicon nitride layer or a combination of both (not shown) covering the substrate and then etching back until the surface of gate conductive layer 212a is exposed.

As shown in FIG. 2F, using the patterned gate conductive layer 212a and the sidewall spacers 216 as masks, source/drain (S/D) implantation is performed to form S/D regions 220 in the substrate 200 along both sides of the spacers 216. For example, P-type S/D impurities are implanted into the N-well using the P-doped gate conductive layer and the spacers thereon as masks and with the P-wells covered, and N-type S/D impurities are later implanted into the P-wells using the N-doped gate conductive layer and spacers thereon as masks and with the N-well covered. Therefore, the PMOS transistor(s) is formed in the N-well(s) of the periphery region, while the NMOS transistors are formed in the P-wells in the memory region and the periphery region.

Referring to FIG. 2G, blocking spacers 218 are then formed on the spacers 216. The blocking spacers can be formed by forming another blanket layer of silicon oxide or silicon nitride (not shown) covering the substrate and between the word lines, and then etching back until the gate conductive layer is exposed, for example. A patterned photoresist layer with the predetermined pattern for salicide formation may be applied, so that the regions to be formed with salicide are exposed during the etching. For the memory region 22 with a dense pattern, blocking spacers 218 are preferably formed on the spacers 216, fill the gaps between spacers 216 and cover the S/D regions 220. That is, the blocking spacers 218 can block the un-wanted code impurities by filling gaps between the gate structures (word lines) and hence preventing the code impurities being mistakenly implanted to the underlying substrate and S/D regions 220.

Referring to FIG. 2H, a third patterned photoresist layer 221 having a code pattern is applied as a mask, and then the code implantation is performed to the memory region 22. For example, N-type impurities (such as, phosphorous) are implanted through the gate conductive layer 212a and the gate oxide layer 210 to the underlying channel regions of the substrate 200. During the code implantation, even if misalignment occurs, the spacers 216 and the blocking spacers 218 can block the code impurities from being doped to the underlying substrate and the S/D regions 220. Therefore, the misalignment tolerance of the code implantation is greatly increased. Accordingly, due to the formation of the spacers 216 and the blocking spacers 218, the code implantation can be performed in a self-aligned way. The code implanted channel regions are marked by dots (∘), and the code implanted memory cells (transistors) are marked with “1” in this figure.

In FIG. 2I, an interlayer dielectric (ILD) 224 is formed to cover the substrate 200 by deposition and then contact holes 225 are formed in the ILD 224. A salicide layer 222 may be formed before depositing the ILD 224. The salicide layer 222 can be formed a blanket metal layer over the substrate, performing a thermal treatment to react the exposed silicon with the metal, and then removing the un-reacted metal by etching. If necessary, barrier layer (not shown) is conformally formed to cover surfaces of the contact holes 225. Then contact plugs 226 are formed within the contact holes 225 by, for example, depositing a tungsten layer (not shown) to fill the contact holes and then planarizing the tungsten layer. The contact piugs can be used to connect the word line to the bit line or other electrical sources. Subsequently, the backend processes including the metallization process are performed. The metallization process comprises forming a metal layer 228 over the interlayer dielectric and then patterning the metal layer, for example.

As described above, by forming the spacers and the blocking spacers, the code implantation can be performed in a self-aligned way into the channel regions of predetermined memory cells. By avoiding erroneous implantation to the non-channel regions and thus the laterally diffusion of the un-wanted impurities to the channel regions of non-coded memory cells, the threshold voltage of the non-coded memory cells can be unaffected and the error rate of reading can be greatly reduced.

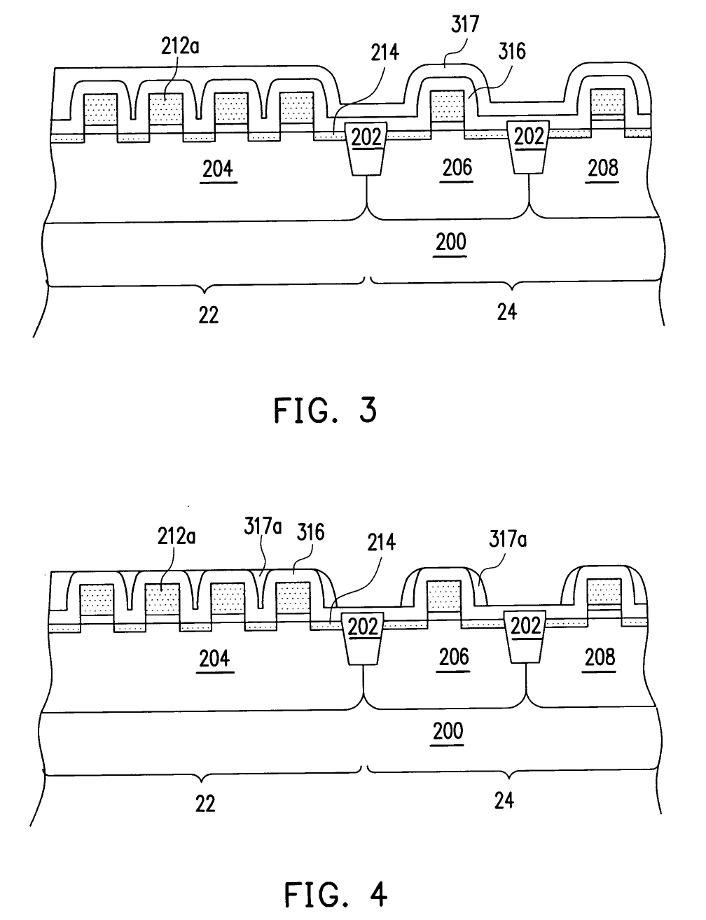

After the process steps described in FIGS. 2A-2D, alternatively, according to the second preferred embodiment, different process steps are illustrated as shown in FIGS. 3-8. However, the same references used in FIGS. 2A-2D are used to represent the same elements. As shown in FIG. 3, after forming the LDD regions 214, a silicon nitride layer 316 is blanketly formed over the substrate 200 and the gate structures. The silicon nitride layer 316 can be formed by chemical vapor deposition and has a thickness of about 500-3000 Angstroms, for example. Next, a silicon oxide layer 317 is formed covering the silicon nitride layer 316 and over the substrate 200 by, for example, chemical vapor deposition. Depending on the dimension of the memory cell and the step coverage of the silicon nitride layer 316, the silicon oxide layer 317 at least fill up the gaps of the silicon nitride layer 316 between the gate structures in the memory region 22.

Referring to FIG. 4, the silicon oxide layer 317 is then etching back until the top surface of the silicon nitride layer 316 is substantially exposed, by time-control etching, for example.

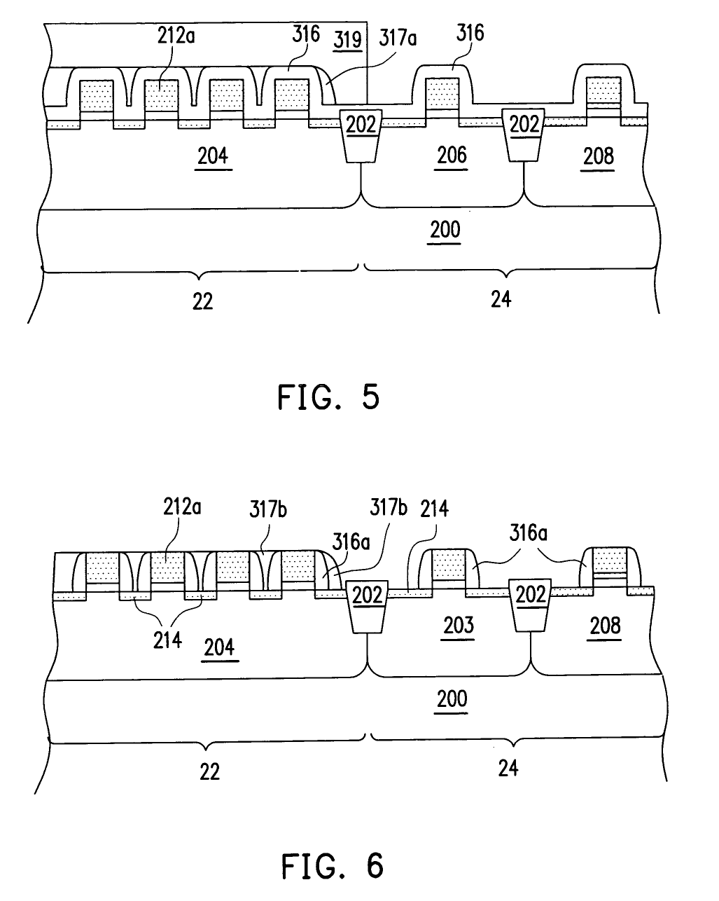

Referring to FIG. 5, a fourth patterned photoresist layer 319 is formed covering the memory region 22, leaving the periphery region 24 being exposed. The fourth patterned photoresist layer 319 covers the remained silicon oxide layer 317a in the memory region 22, while the silicon oxide layer in the periphery region 24 is exposed. An oxide etching process, for example, a wet etching process with high selectivity of silicon oxide to silicon nitride, is performed, so as to remove the exposed silicon oxide layer 317a in the periphery region 24. The silicon nitride layer 316 in the periphery region 24 is hence exposed.

Referring to FIG. 6, after removing the fourth patterned photoresist layer 319, an etching back process is performed until the gate conductive layer 212a is exposed. This etching back process, for example, is a dry etching process with the silicon oxide/silicon nitride selectivity of about 1. Through the etching back process, the silicon oxide layer 317a in the memory region 22 and the silicon nitride layer 316 in both the memory and the periphery regions 22/24 are simultaneously removed. Hence, nitride spacers 316a are formed on sidewalls of the gate structures in the periphery region 24, while nitride spacers 316a and oxide spacers 317b are formed on sidewalls of the gate structures in the memory region 22. The oxide spacers 317b are disposed on the nitride spacers 316a and between the nitride spacers 316a in the memory region 22, thus covering the underlying LDD regions 214 in the memory region 22. That is, the nitride and oxide spacers 316a/317b can block the un-wanted code impurities by filling gaps between the gate structures (word lines) and hence preventing the code impurities being mistakenly implanted to the underlying substrate and S/D regions 220.

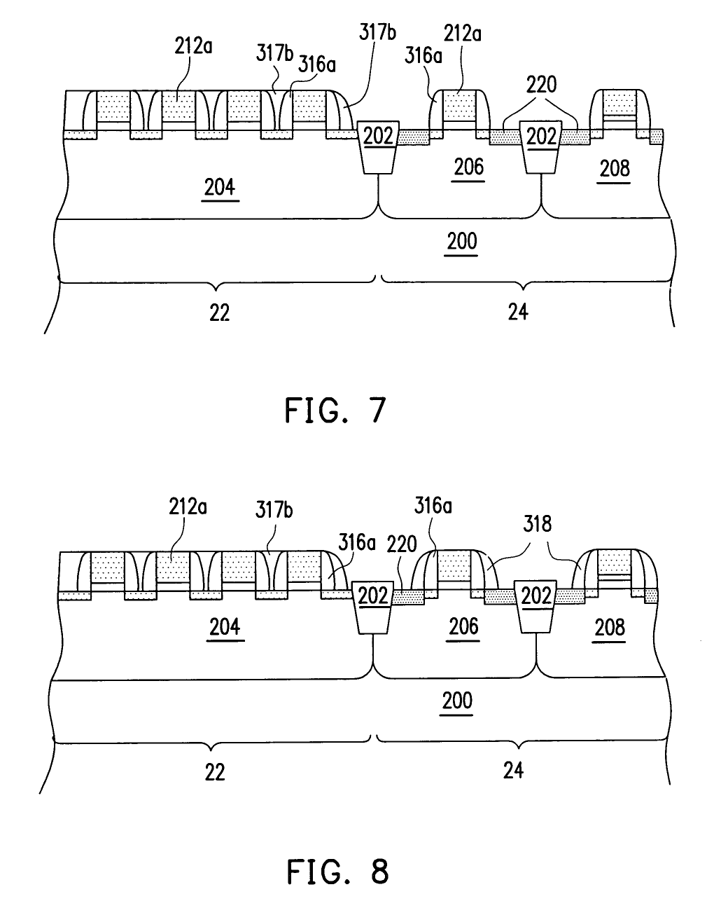

As shown in FIG. 7, using the patterned gate conductive layer 212a and the sidewall spacers 316a as masks, source/drain (S/D) implantation is performed to form S/D regions 220 in the periphery region 24 of the substrate 200 along both sides of the spacers 316a. The details are similar as described in the process of FIG. 2F.

Optionally, following the process steps described in FIG. 7, auxiliary spacers 318 can be selectively formed on the spacers 316a (as shown in FIG. 8). The auxiliary spacers 318 may be formed by blanketly forming a silicon oxide layer or a silicon nitride layer (not shown) covering the substrate and then etching back. Using a patterned photoresist layer with the predetermined pattern for salicide formation may be applied, the regions to be formed with salicide are exposed during etching back. The auxiliary spacers 318 can assist the blockage of the un-wanted code impurities being mistakenly implanted to the underlying substrate and S/D regions 220.

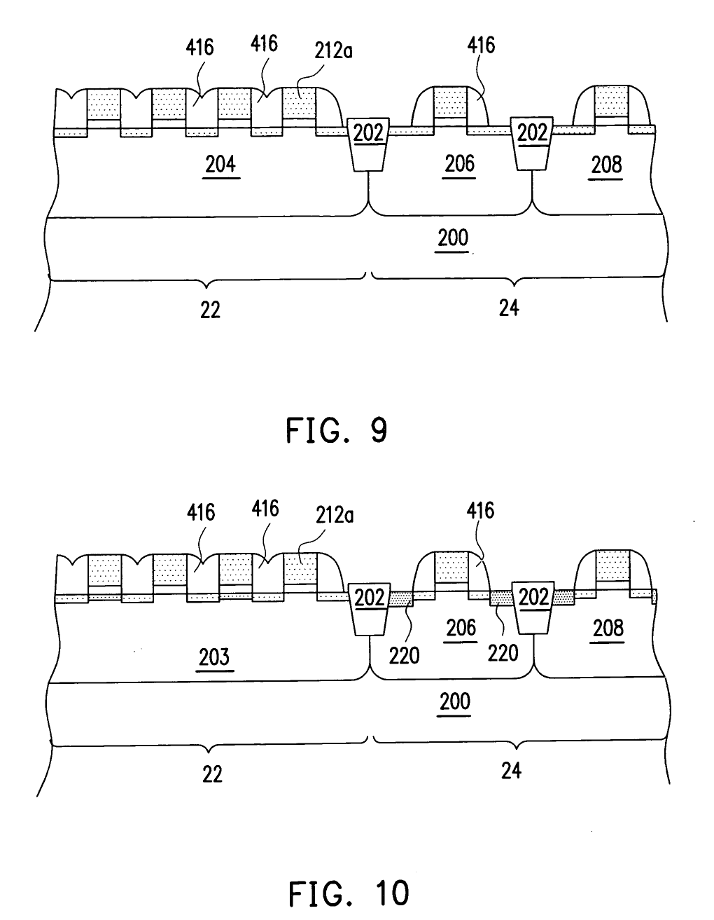

Alternatively, according to the third preferred embodiment, the process steps illustrated in FIGS. 3-6 can be replaced with the process steps illustrated in FIG. 9. After forming the LDD regions (i.e. after the process steps described in FIGS. 2A-2D), spacers 416 are formed on the sidewalls of the patterned gate conductive layer 212a. For example, the spacers 216 can be formed by forming a blank layer (not shown) having a thickness of about 500-3000 Angstroms covering the substrate and then etching back until the surface of gate conductive layer is exposed. The blanket layer may be a silicon oxide layer, a silicon nitride layer or a combination of both, while the etching back process may be a time-control dry etching process. By controlling the etching back process, the spacers 416 between the gate structures in the memory region 22 are connected and completely cover the exposed substrate 200 between the gate structures in the memory region 22 (as shown in FIG. 9). Namely, the spacers 416 can block the un-wanted code impurities by filling gaps between the gate structures (word lines) and hence preventing the code impurities being mistakenly implanted to the underlying substrate and S/D regions 220.

Following the process steps in FIG. 9, as shown in FIG. 10, using the patterned gate conductive layer 212a and the sidewall spacers 416 as masks, source/drain (S/D) implantation is performed to form S/D regions 220 in the periphery region 24 of the substrate 200 along both sides of the spacers 416. The details are similar as described in the process of FIG. 2F.

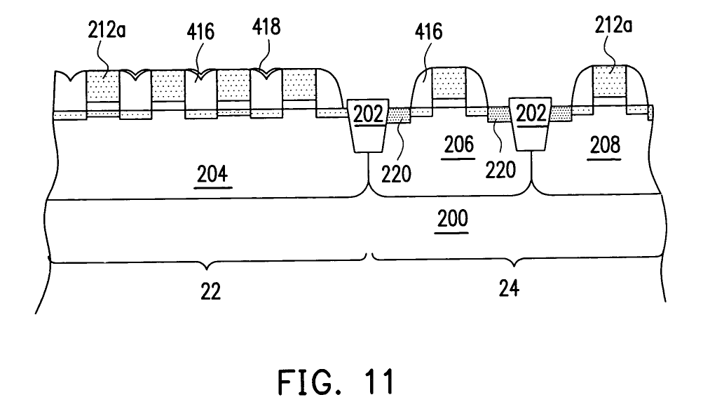

Optionally, after the process steps described in FIG. 10, auxiliary spacers 418 can be selectively formed on the spacers 416 (in FIG. 11). The auxiliary spacers 418 may be formed by blanketly forming a silicon oxide layer or a silicon nitride layer (not shown) covering the substrate and then etching back. Using a patterned photoresist layer with the predetermined pattern for salicide formation may be applied, the regions to be formed with salicide are exposed during etching back. The auxiliary spacers 418 can assist the blockage of the un-wanted code impurities being mistakenly implanted to the underlying substrate and S/D regions 220.

The following process steps of the second and the third preferred embodiment are similar as the process steps described in FIGS. 2H-2I, and will not be described in details. Under different conditions, the auxiliary spacers can be formed after performing the code implantation.

Similarly, during the code implantation, even if misalignment occurs, the spacers 316a/317b or 416 and/or the auxiliary spacers 318/418 can block the code impurities from being doped to the underlying substrate and the S/D regions 220. Therefore, the misalignment tolerance of the code implantation is greatly increased. Accordingly, due to the formation of the spacers 316a/317b or 416 and/or the auxiliary spacers 318/418, the code implantation can be performed in a self-aligned way.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for forming a mask read only memory structure, comprising:
providing a substrate having a memory region and a periphery region;
performing a threshold voltage implantation to adjust a threshold voltage of the memory region;
forming a plurality of gate structures on the substrate, wherein the gate structure includes a gate oxide layer on the substrate and a gate conductive layer on the gate oxide layer;
forming a plurality of first spacers on sidewalls of the gate structures, wherein gaps between the first spacers expose a portion of substrate;
forming a plurality of source/drain regions in the substrate along both sides of the first spacers, by performing a source/drain implantation using the gate structures and the first spacers as masks;
forming a plurality of second spacers on the first spacers, wherein the second spacers on the first spacers in the memory region fill the gaps between the first spacers and cover the source/drain regions in the memory region;
applying a patterned photoresist layer with a code pattern to the substrate and then performing a code implantation to the memory region using the patterned photoresist layer with the code pattern as a mask;
removing the patterned photoresist layer;
forming an interlayer over the substrate; and
forming at least a contact plug in the interlayer.

2. The method of claim 1, further comprising forming a plurality of lightly doped drain (LDD) regions in the substrate along both sides of the gate structures before forming the first spacers on the sidewalls of the gate structures.

3. The method of claim 1, wherein a material of the first spacer is silicon oxide or silicon nitride.

4. The method of claim 1, wherein a material of the second spacer is silicon nitride or silicon oxide.

5. A method for forming a mask read only memory structure, comprising:
providing a substrate having a memory region and a periphery region;
performing a threshold voltage implantation to adjust a threshold voltage of the memory region;
forming a plurality of gate structures on the substrate, wherein the gate structure includes a gate oxide layer on the substrate and a gate conductive layer on the gate oxide layer;
forming a plurality of lightly doped regions in the substrate along both sides of the gate structures, by performing an implantation using the gate structures as masks;
forming a plurality of spacers on sidewalls of the gate structures;
forming a plurality of source/drain regions in the substrate along both sides of the spacers in the periphery region, by performing a source/drain implantation using the gate structures and the spacers as masks, wherein the spacers on the sidewalls of the gate structures in the memory region completely cover the source/drain regions in the memory region;
applying a patterned photoresist layer with a code pattern to the substrate and then performing a code implantation to the memory region using the patterned photoresist layer with the code pattern as a mask;
removing the patterned photoresist layer;
forming an interlayer over the substrate; and
forming at least a contact plug in the interlayer.

6. The method of claim 5, wherein the step of forming the spacers comprises:
forming sequentially a silicon nitride layer and a silicon oxide layer covering the gate structures and the substrate;
removing the silicon oxide layer by etching back until the silicon nitride layer is exposed;
removing the remained silicon oxide layer in the periphery region so as to expose the silicon nitride layer in the periphery region; and
removing the remained silicon oxide layer in the memory region and the silicon nitride layer in both the memory region and the periphery region, so as to obtain a plurality of nitride spacers on the sidewalls of the gate structures in both the memory region and the periphery region and a plurality of oxide spacers on the nitride spacers in the memory region.

7. The method of claim 6, further comprising forming a plurality of auxiliary spacers on the nitride spacers after performing the code implantation.

8. The method of claim 6, further comprising forming a plurality of auxiliary spacers on the nitride spacers before performing the code implantation.

9. The method of claim 5, wherein the step of forming the spacers comprises:
forming an insulating layer covering the gate structure and the substrate; and
removing the insulating layer by time-control etching back until a top surface of the gate structure is exposed, so that the spacers in the memory region are formed on the sidewalls of the gate structures and between the gate structures.

10. The method of claim 9, further comprising forming a plurality of auxiliary spacers on the spacers after performing the code implantation.

11. The method of claim 9, further comprising forming a plurality of auxiliary spacers on the spacers before performing the code implantation.

12. The method of claim 9, wherein a material of the insulation layer is silicon oxide or silicon nitride.
